(19) United States
(12) Patent Application Publication
(10) Pub. No.: US 2017/0104185 A1
(43) Pub. Date: Apr. 13, 2017

(54) FILM FORMING MASK, FILM FORMING METHOD AND METHOD FOR MANUFACTURING DISPLAY DEVICE

(71) Applicant: Japan Display Inc., Tokyo (JP)

(72) Inventor: Taiki WATANABE, Tokyo (JP)

(21) Appl. No.: 15/283,834

(22) Filed: Oct. 3, 2016

(30) Foreign Application Priority Data
Oct. 9, 2015 (JP) 2015-200955

(51) Int. Cl. H01L 51/56; C23C 16/04; H01L 51/00; H01L 51/52; H01L 27/32

(52) U.S. Cl. CPC H01L 51/56; H01L 51/5253; H01L 27/3244; H01L 51/0011; C23C 16/042; H01L 2227/323; H01L 51/5012

(57) ABSTRACT

A film-forming mask includes a mask body having a first surface facing a film forming surface, a second surface opposite to the first surface, and an opening exposing a part of the film forming surface. The mask body is thinned from the side of the first surface along an edge of the opening.

### CROSS REFERENCE TO RELATED APPLICATIONS

This application is based upon and claims the benefit of priority from the prior Japanese Patent Application No. 2015-200955 filed on Oct. 9, 2015, the entire contents of which are incorporated herein by reference.

### FIELD

The present invention relates to a structure of a film-forming mask, and a film forming method using the same.

### BACKGROUND

A display device includes a light-emitting element in each of a plurality of pixels and displays an image by controlling light emission in each of the pixels individually. For example, an organic EL display device using an organic EL element as a light-emitting element includes an organic EL element in each of pixels. The organic EL element includes a pair of electrodes, one of which is an anode and the other of which is a cathode, and a layer containing an organic EL material (hereinafter, referred to also as an “organic EL layer”) is held between the pair of electrodes. In such an organic EL display device, one of the electrodes is provided as a pixel electrode, and the other electrode is provided as a common electrode supplied with a common potential and covering to the plurality of pixels. The organic EL display device controls light emission of each of the pixels by applying a potential to the pixel electrode pixel-by-pixel.

For manufacturing a display device, an organic film used as a light-emitting layer is formed by vapor deposition by a method using a film formation mask having an opening in an area where the organic film is to be formed (e.g., Japanese Laid Open Patent Publication No. Hei 10-265940). However, with this method, an array substrate and the film formation mask contact with each other. This involves a risk that the mask directly damages the array substrate or that a foreign object, if being attached to the mask, is transferred to the array substrate. Such a damage or foreign object may destroy a circuit in the array substrate or make a pass allowing moisture to enter the display device. This may cause a driving failure or a dark edge.

Japanese Laid-Open Patent Publication No. Hei 10-265940 describes a method for manufacturing a film formation metal mask. According to this method, a metal plate is etched to form a film forming opening, and an edge portion of a shielding region usable to form the opening is half-etched from the side of the surface on which the film is to be formed. The above-mentioned publication also describes a method for manufacturing a film forming metal mask. According to this method, a metal plate is etched to form a film forming opening, and at the same time, a substantially central portion of the shielding region is partially half-etched from the side of the substrate.

The film forming metal mask manufactured by any of the above-described methods has the edge portion of the shielding region contact with the substrate at the time of film formation. In the case where, for example, a transistor, a wiring connected to the transistor, or the like is located just below the edge portion of the shielding region, the transistor or the like may be damaged by contact with the film forming metal mask. The above-described methods do not consider such a damage. If such a damage is made, the yield of the display devices may be decreased.

The present invention provides a film-forming mask avoiding an element located just below a shielding region of the film-forming mask from being damaged during film formation, and a film forming method using the same.

### SUMMARY

In an embodiment according to the present invention, a film-forming mask includes: a mask body having a first surface facing a film forming surface; a second surface opposite to the first surface; and an opening exposing a part of the film forming surface. The mask body is thinned from the side of the first surface along an edge of the opening.

In an embodiment according to the present invention, a method for manufacturing a display device includes: forming, on a film forming surface of a substrate, a display region including a plurality of pixel electrodes forming a plurality of pixels, a driving circuit region including a transistor, the driving circuit region being formed outer to the display region, and a sealing region enclosing the display region, the sealing region being formed outer to the driving circuit region; putting a first surface of a film-forming mask into contact with the film forming surface, the film-forming mask including the first surface facing the film forming surface, a second surface opposite to the first surface, and an opening exposing the display region, the mask being thinned from the side of the first surface in at least a region including the driving circuit region; and forming a light-emitting layer containing an organic material.

### BRIEF DESCRIPTION OF DRAWINGS

FIG. 1A is a plan view showing a structure of a film-forming mask in an embodiment according to the present invention;

FIG. 1B is a cross-sectional view showing the structure of the film-forming mask in the embodiment according to the present invention;

FIG. 2 is a cross-sectional view showing a positional arrangement of the film-forming mask in the embodiment according to the present invention during film formation;

FIG. 3A is a cross-sectional view showing a film forming method using a film-forming mask in an embodiment according to the present invention;

FIG. 3B is a cross-sectional view showing the film forming method using the film-forming mask in the embodiment according to the present invention;

FIG. 4A is a plan view showing a structure of a film-forming mask in a modification of the embodiment according to the present invention;

FIG. 4B is a cross-sectional view showing the structure of the film-forming mask in the modification of the embodiment according to the present invention;

FIG. 5A is a plan view showing a structure of a film-forming mask in another modification of the embodiment according to the present invention;

FIG. 5B is a cross-sectional view showing the structure of the film-forming mask in the another modification of the embodiment according to the present invention;

FIG. 6A is a plan view showing a structure of a film-forming mask in still another modification of the embodiment according to the present invention;

FIG. 6B is a cross-sectional view showing the structure of the film-forming mask in the still another modification of the embodiment according to the present invention;

FIG. 7 is a perspective view showing a schematic structure of a display device manufactured by a display device manufacturing method in an embodiment according to the present invention;

FIG. 8 is a cross-sectional view showing the structure of the display device manufactured by the display device manufacturing method in the embodiment according to the present invention;

FIG. 9 is a plan view showing a method for manufacturing a display device in an embodiment according to the present invention;

FIG. 10A is a plan view showing a film-forming mask used for the method for manufacturing a display device in an embodiment according to the present invention;

FIG. 10B is a cross-sectional view showing the film-forming mask used for the method for manufacturing a display device in the embodiment according to the present invention;

FIG. 11 is a cross-sectional view showing the method for manufacturing a display device in the embodiment according to the present invention;

FIG. 12 is a cross-sectional view showing the method for manufacturing a display device in the embodiment according to the present invention;

FIG. 13 is a cross-sectional view showing the method for manufacturing a display device in the embodiment according to the present invention; and

FIG. 14 is a cross-sectional view showing the method for manufacturing a display device in the embodiment according to the present invention.

### DESCRIPTION OF EMBODIMENTS

Hereinafter, embodiments of the present invention will be described with reference to the drawings and the like. The present invention may be carried out in various other embodiments, and should not be construed as being limited to any of the following embodiments. In the drawings, components may be shown schematically regarding the width, thickness, shape and the like, instead of being shown in accordance with the actual sizes, for the sake of clear illustration. The drawings are merely exemplary and do not limit the interpretations of the present invention in any way. In the specification and the drawings, components that are substantially the same as those shown in a previous drawing(s) bear the identical reference signs thereto, and detailed descriptions thereof may be omitted.

### Embodiment 1

With reference to the figures, a structure of a film-forming mask 100 in this embodiment and a film forming method using the same will be described.

### [Structure]

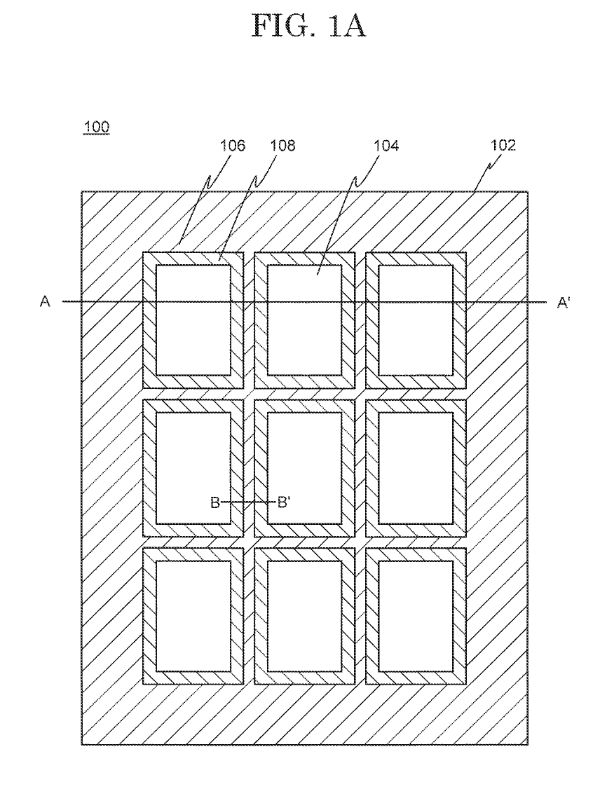

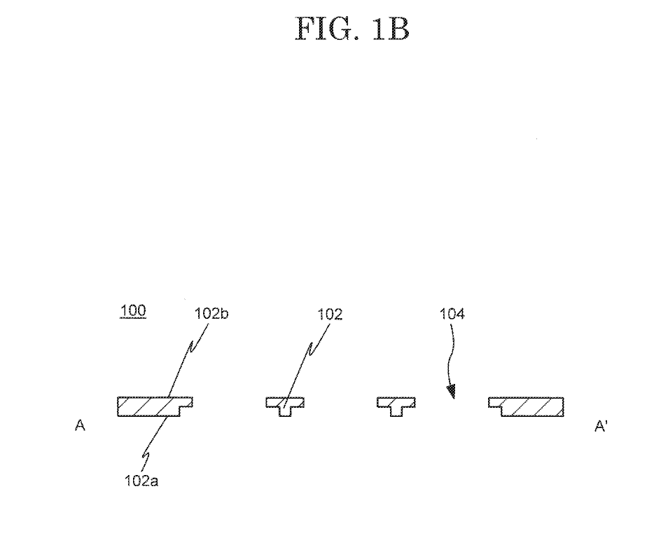

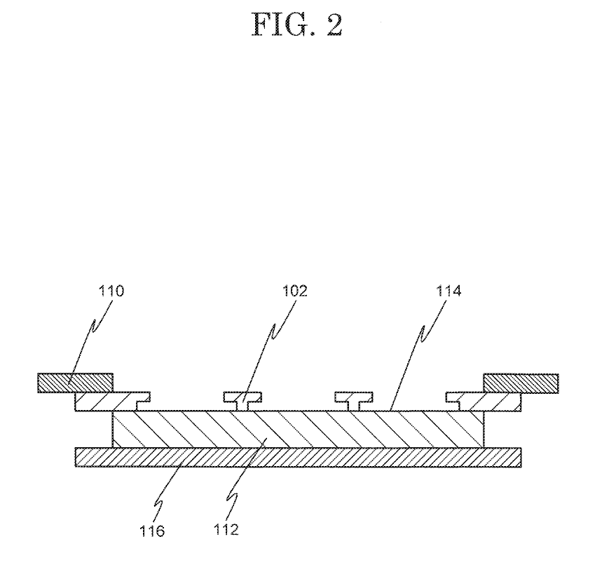

FIG. 1A and FIG. 1B are respectively a plan view and a cross-sectional view showing a structure of the film-forming mask 100 in this embodiment. FIG. 1A is a plan view of the film-forming mask 100, and FIG. 1B is a cross-sectional view thereof taken along line A-A′ in FIG. 1A. FIG. 2 is a cross-sectional view showing a positional arrangement of the film-forming mask 100 in this embodiment during film formation.

The film-forming mask 100 in this embodiment includes a first surface 102a facing a surface on which a film is to be formed (hereinafter, referred to as a “film forming surface”), and a second surface 102b opposite to the first surface 102a. The film-forming mask 100 includes a mask body 102 including an opening 104, a first shielding region 106, and a second shielding region 108. In this example, the mask body 102 includes an array of a plurality of the openings 104. Specifically, rectangular openings 104 are arrayed in a matrix of 3 rows by 3 columns.

The openings 104 expose a part of a film forming surface 114. The second shielding region 108 is a region along an edge of each of the openings 104 and is thinned from the side of the first surface 102a. The first shielding region 106 is a region of the mask body 102 other than the openings 104 and the second shielding regions 108. In other words, on the first surface 102a, the first shielding region 106 is located closer to the film forming surface 114 than the second shielding regions 108. In still other words, in the state where the film forming surface 114 of a substrate 112 and the first shielding region 106 contact with each other, there is a gap between the film forming surface 114 of the substrate 112 and the second shielding region 108 of the film-forming mask 100. In still other words, the second shielding regions 108, which are eaves-like, extend from an end of the first shielding region 106 toward the openings 104.

The film-forming mask 100 in this embodiment includes the second shielding region 108 along the edge of each opening 104. In this example, the second shielding region 108 is located to enclose the edge of the opening 104. The region of the film-forming mask 100 other than the openings 104 and the second shielding regions 108 is the first shielding region 106.

In this example, the second shielding regions 108 respectively located to enclose the plurality of openings 104 are separated from each other. In other words, the first shielding region 106 is located to enclose an edge of the second shielding region 108 around each of the openings 104.

Because of such a structure, the first shielding region 106 has a role of a beam, which improves the strength of the film-forming mask 100.

The film-forming mask 100 in this embodiment may further include a mask frame 110 provided along an outer periphery of the mask body 102. Referring to FIG. 2, the mask body 102 is supported by the mask frame 110 during film formation and is located on the film forming surface 114 of the substrate 112. On a surface of the substrate 102 opposite to the film forming surface 114, a magnet 116 securing the film-forming mask 100, which is formed of a metal, to the substrate 112 may be provided.

In this example, a surface of the first shielding region 106 that faces the film forming surface 114 of the substrate 112 lie on a plane, and a surface of the second shielding regions 108 that faces the film forming surface 114 of the substrate 112 lie on another plane. Namely, a surface of the film-forming mask 100 facing the film forming surface 114 of the substrate 112 has a two-stage structure including one plane on which the first shielding region 106 is located and another plane on which the second shielding regions 108 are located. The surface of the first shielding region 106 facing the film forming surface 114 of the substrate 112, and the surface of the second shielding regions 108 facing the film forming surface 114 of the substrate 112, form a step at a border therebetween.

An area of the film forming surface 114 of the substrate 112 that overlaps the first shielding region 106 of the film-forming mask 100 is in contact with the film-forming mask 100. Therefore, a thin film is not deposited on this area. Areas of the film forming surface 114 of the substrate 112 that overlap the second shielding regions 108 are not in contact with the film-forming mask 100, but are covered with the second shielding regions 108. Therefore, a thin film is not deposited on these areas.

Such a structure allows a thin film to be selectively deposited on areas corresponding to the openings 104 of the film-forming mask 100, and also avoids a damage from being caused by the contact of the film-forming mask 100 and the film forming surface 114. Even if a foreign object is attached to the second shielding regions 108, the gap made between the second shielding regions 108 and the film forming surface 114 suppresses the foreign object from being attached to the film forming surface 114 of the substrate 112 after the film is formed.

The film-forming mask 100 having such a structure may be manufactured as follows. Areas corresponding to the second shielding regions 108 of the metal plate used to form the mask body 102 are half-etched.

### [Film Forming Method]

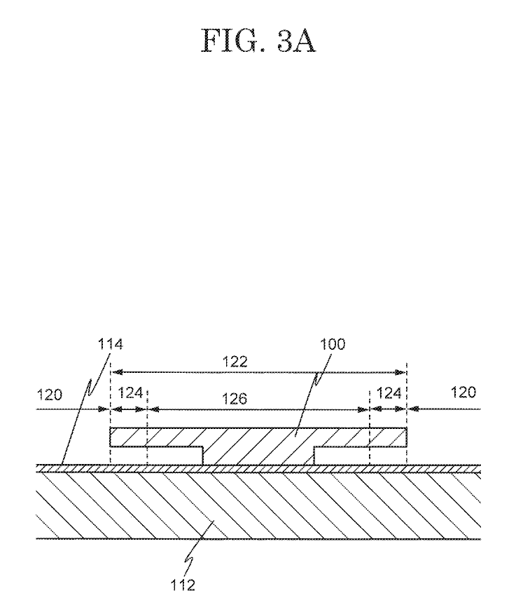

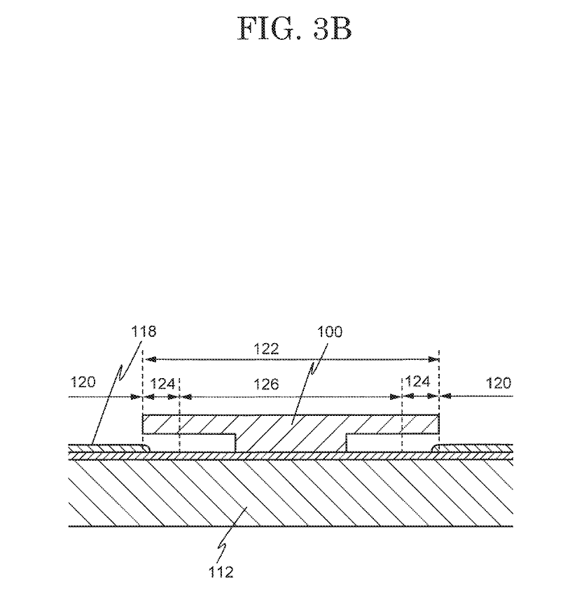

FIG. 3A and FIG. 3B are cross-sectional views showing a film forming method using the film-forming mask 100 in this embodiment, taken along line B-B′ in FIG. 1A. FIG. 3A is a cross-sectional view showing a state where the film-forming mask 100 is located on the substrate 112 but a thin film 118 has not been formed yet. FIG. 3B is a cross-sectional view showing a state where the thin film 118 is formed on the substrate 112 by use of the film-forming mask 100.

For forming the thin film 118, the film forming surface 114 of the substrate 112 is classified into a film forming region 120 and a film formation prohibited region 122. The film forming region 120 is a region where the thin film 118 is deposited, and the film formation prohibited region 122 is a region where the thin film 118 is not formed. The film formation prohibited region 122 is the region of the film forming surface 114 other than the film forming region 120.

In film formation performed using a film-forming mask of the conventional art, a film formation prohibited region and a shielding region of the film-forming mask are put into close contact with each other so that the formation of the thin film is prevented in these regions. However, there is a case where it is not preferable that the film formation prohibited region and the film-forming mask contact with each other. In the case where, for example, a circuit including a transistor, a wiring connected to the transistor and the like is located in the film formation prohibited region, the contact with the film-forming mask may destroy the circuit. This may decrease the yield of the display devices.

In such a situation, the film forming method in this embodiment classifies the film formation prohibited region 122 into a contact prohibited region 124 and a contact permitted region 126. The contact prohibited region 124 is a region where the contact with the film-forming mask 100 is not preferable for the above-described reason or the like. The contact permitted region 126 is a region where the contact with the film-forming mask 100 is permissible.

With the film forming method using the film-forming mask 100 in this embodiment, as shown in FIG. 3A and FIG. 3B, the second shielding regions 108 are each located to overlap the contact prohibited region 124. In the case where the thin film 118 is formed in this state, the thin film 118 is prevented from being deposited on the contact prohibited region 124 without contacting the contact prohibited region 124 with the film-forming mask 100.

In the case where the gaps between the film forming surface 114 of the substrate 112 and the second shielding regions 108 have a certain width, the material of the thin film 118 may possibly be deposited in the vicinity of the edges of the second shielding regions 108 when the thin film 118 is formed. In such a case, the locations of the edges of the second shielding regions 108 and the width of the gaps between the film forming surface 114 of the substrate 112 and the second shielding regions 108 may be adjusted at the time of designing of the film-forming mask 100 in consideration of the amount of the material of the thin film 118 that may be deposited in the vicinity of the edges of the second shielding regions 108.

More specifically, the edges of the second shielding regions 108 may be located outside of the film forming region 120, so that the thin film 118, when being deposited, matches the film forming region 120.

In addition, the height of the gaps between the film forming surface 114 of the substrate 112 and surface of the second shielding regions 108 may be decreased to reduce the amount of the material of the thin film 118 that may be deposited in the vicinity of the edges of the second shielding regions 108.

The film forming method in this embodiment is applicable to film forming techniques such as chemical vapor deposition (CVD), sputtering, and vapor deposition. The amount of the material of the thin film 118 that may be deposited in the vicinity of the edges of the second shielding regions 108 varies in accordance with the film forming method, the film forming conditions, the type of the film, and the like. Therefore, the height of the clearances between the film forming surface 114 and surface of the second shielding regions 108 may be appropriately adjusted in consideration of these factors.

<Modification 1>

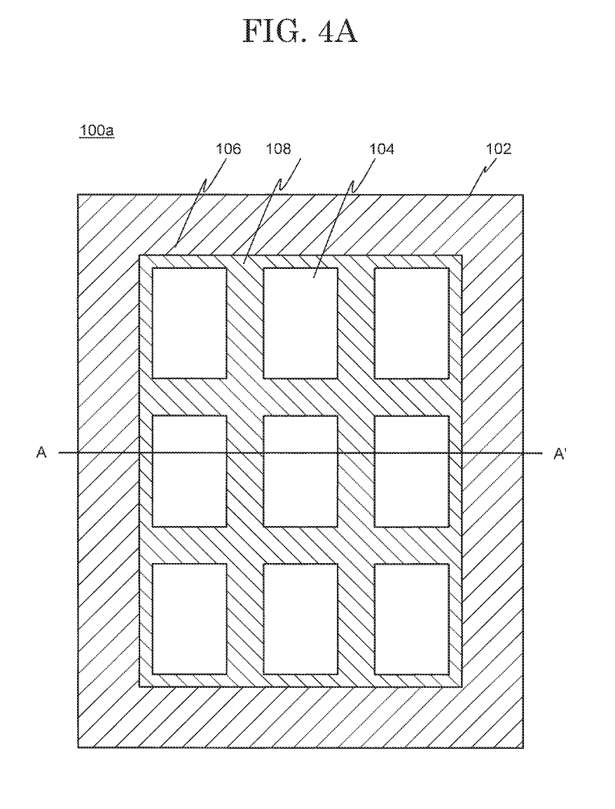

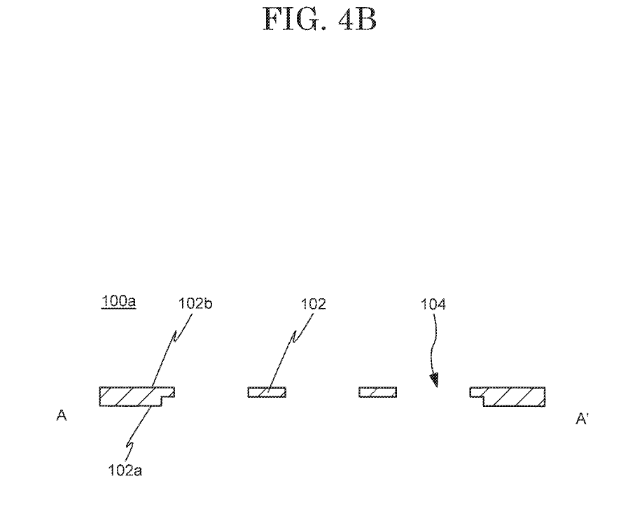

A structure of a film-forming mask 100a in a modification of this embodiment will be described. FIG. 4A and FIG. 4B are respectively a plan view and a cross-sectional view of the film-forming mask 100a in this modification.

The film-forming mask 100a in modification 1 and the film-forming mask 100 in embodiment 1 are different from each other in the planar shape of the second shielding region 108. In this modification, the second shielding region 108 encloses all the rectangular openings 104 provided in a matrix of three rows by three columns. Namely, one thinned region encloses all the plurality of openings 104 arrayed in the film-forming mask 100. In other words, the first shielding region 106 is located at least along an outer periphery of the mask body 102 formed of a metal plate.

Such a structure makes it unnecessary to provide the contact permitted region 126 in the substrate 112. Therefore, the region of the substrate 112 is utilized to a maximum possible degree.

Even such a layout prevents the thin film 118 from being deposited on the contact prohibited region 124 without contacting the contact prohibited region 124 with the film-forming mask 100a.

### <Modification 2>

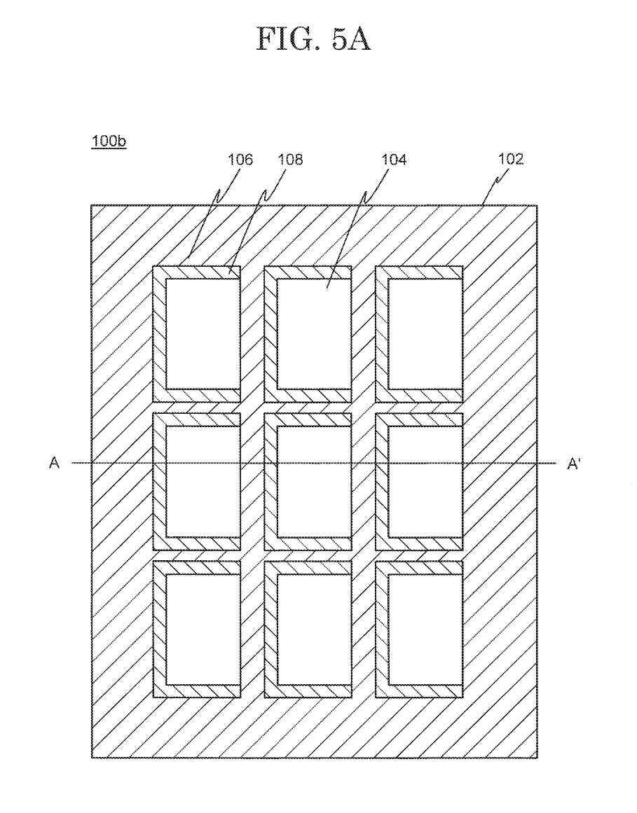

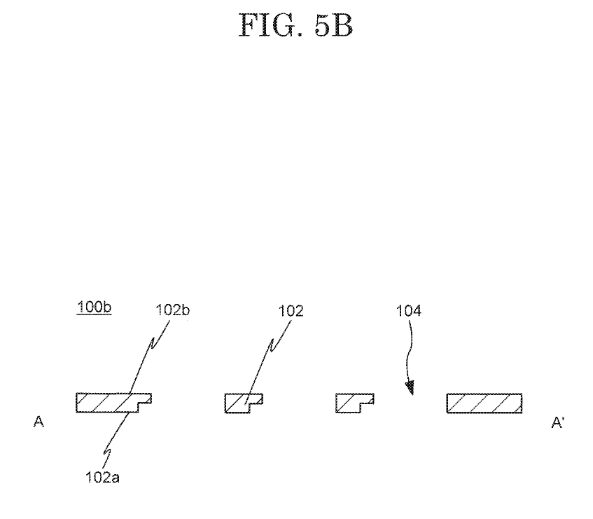

A structure of a film-forming mask 100b in another modification of this embodiment will be described. FIG. 5A and FIG. 5B are respectively a plan view and a cross-sectional view of the film-forming mask 100b in this modification.

The film-forming mask 100b in modification 2 and the film-forming mask 100 in embodiment 1 are different from each other in the planar shape of the second shielding regions 108. In this modification, the first shielding region 106 is adjacent to one side of each of the rectangular openings 104. As can be seen from this modification, the second shielding regions 108 do not need to enclose all the sides of each of the openings 104.

<Modification 3>

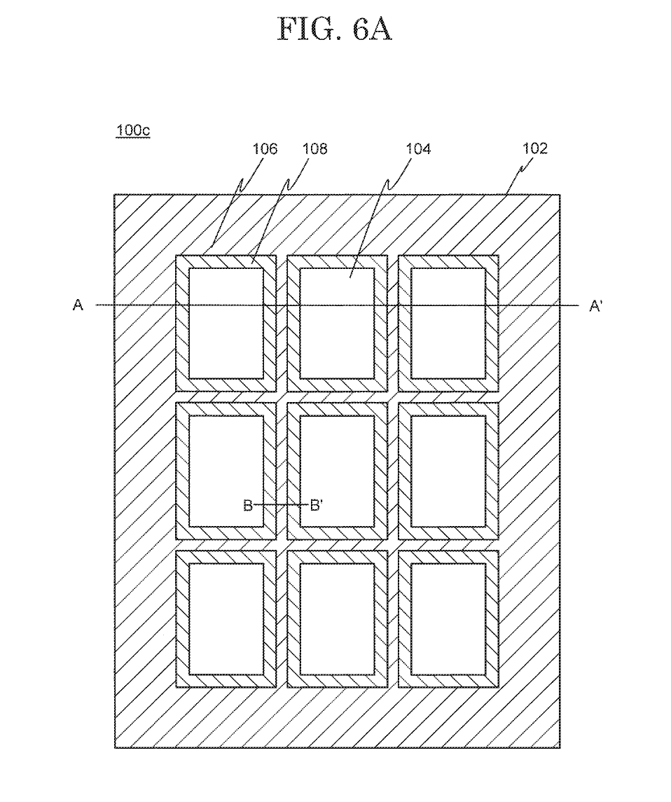

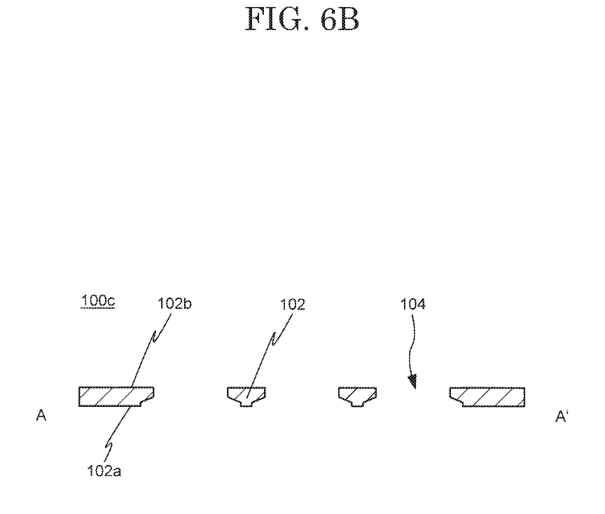

A structure of a film-forming mask 100c in still another modification of this embodiment will be described. FIG. 6A and FIG. 6B are respectively a plan view and a cross-sectional view of the film-forming mask 100c in this modification.

The film-forming mask 100c in modification 3 and the film-forming mask 100 in embodiment 1 are the same as each other in the planar shape but are different from each other in the cross-sectional shape. In the film-forming mask 100 in embodiment 1, the surface of the second shielding regions 108 facing the film forming surface 114 of the substrate 112 lie on the same plane. By contrast, in the film-forming mask 100c in modification 3, the surface of the second shielding regions 108 facing the film forming surface 114 of the substrate 112 does not lie on the same plane. More specifically, such a surface of the second shielding regions 108 is tapered.

Such a structure improves the mechanical strength of the areas in the vicinity of the borders between the first shielding region 106 and the second shielding regions 108.

### Embodiment 2

As an example of application of the film forming method according to the present invention, a method for manufacturing a display device 200 using the film forming method will be described.

### [Structure of the Display Device]

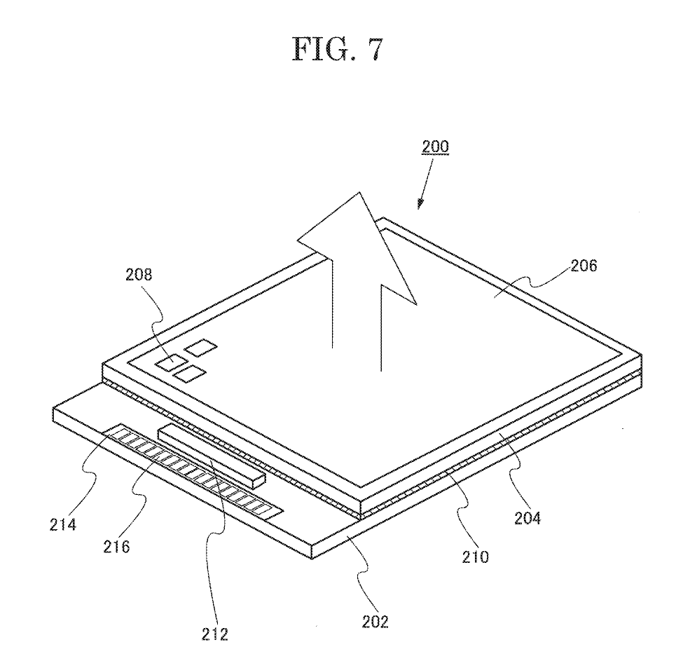

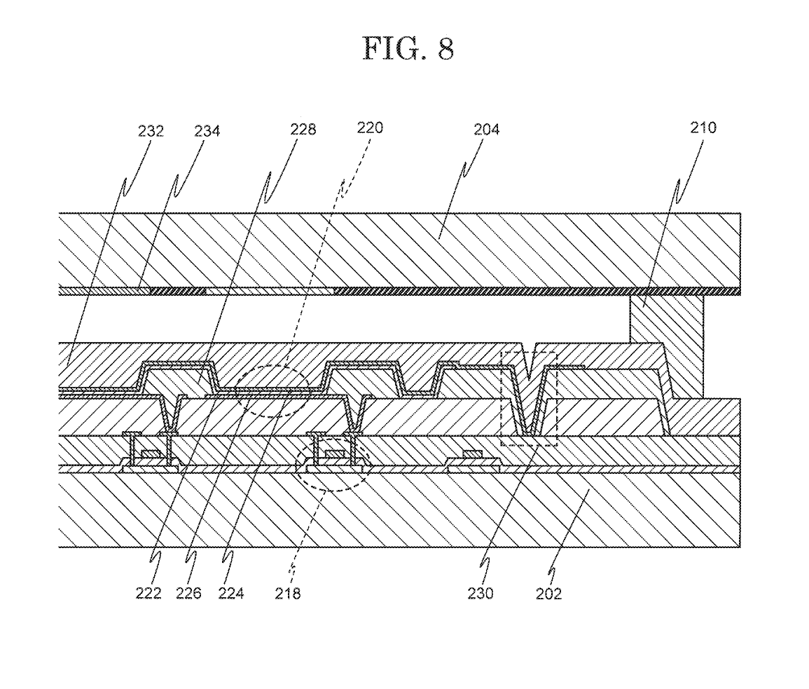

A structure of the display device 200 manufactured by a display device manufacturing method in this embodiment will be described with reference to the figures. FIG. 7 is a perspective view showing a schematic structure of the display device 200 manufactured by use of the display device manufacturing method in this embodiment. FIG. 8 is a cross-sectional view showing a structure of the display device 200 manufactured by use of the display device manufacturing method in this embodiment.

The display device 200 includes a first substrate 202 and a display region 206 provided thereon. The display region 206 includes an array of a plurality of pixels 208. The display device 200 includes a second substrate as a sealing member on a top surface of the display region 206. The second substrate 204 is fixed to the first substrate 202 with a sealing member 210 enclosing the display region 206. The display region 206 formed on the first substrate 202 is sealed by the second substrate 204 and the sealing member 210 so as not to be exposed to the outside air. Such a sealing structure suppresses a light-emitting element provided in each of the plurality of pixels 208 from being deteriorated.

The first substrate 202 has a terminal region 214 provided thereon along an end thereof. The terminal region 214 is located outer to the second substrate 204. The terminal region 214 includes a plurality of connection terminals 216. At each of the connection terminals 216, a wiring board that connects a device outputting a video signal, a power supply or the like with a display panel is provided. A contact of each of the connection terminals 216 with the wiring board is exposed outside.

As shown in FIG. 8, each of the plurality of pixels 208 of the display device 200 includes a transistor 218 and a light-emitting element 220. The light-emitting element 220 includes a pixel electrode 222, a common electrode 224 facing the pixel electrode 222, and a light-emitting layer 226 held between the pixel electrode 222 and the common electrode 224. The pixel electrode 222 is independent in each of the pixels 208 and is connected with the respective transistor 218.

A bank 228 is provided between each two pixels adjacent to each other. The bank 228 is located such that an end of it covers a periphery of each of the pixel electrode 222. The bank 228 prevents a situation where the light-emitting layer 226 does not sufficiently cover the end of the pixel electrode 222 and the pixel electrode 222 is shortcircuited with the common electrode 224. The bank 228 insulates the adjacent pixels 108 from each other. Therefore, it is preferable that the bank 228 is formed of an insulating material. It is preferable that the bank 228 is formed of an organic material such as a polyimide, or an acrylic resin, or an inorganic material such as silicon oxide.

The display device 200 includes a sealing region 230 in the vicinity of an outer periphery thereof. The sealing region 230 has a closed shape as seen in a plan view, and encloses the plurality of pixels 208. In the sealing region 230 having a frame shape, organic films such as the light-emitting layer 226, the bank 228 and the like are removed. Namely, the organic films located inner to the sealing region 230 and the organic films located outer to the sealing region 230 are separated from each other by the sealing region 230. The organic films tend to act as a transporting pass for moisture. The provision of the sealing region 230 blocks a transporting pass for moisture from the outside of the display device 200 to the pixels 208 located inside the display device 200.

The display device 200 in this embodiment has a so-called top emission type structure, in which light generated in the light-emitting element 220 is emitted through the common electrode 224. The display device 200 is of a top emission type in this embodiment, but is not limited to being of this type. The present invention is applicable to a display device of a so-called bottom emission type, in which light generated in the light-emitting element 220 is emitted through the pixel electrode 222.

The light-emitting layer 226 formed of, for example, an organic EL material, is formed of a low molecular weight type organic material or a high molecular weight type organic material. In the case where a low molecular weight type organic material is used to form the light-emitting layer 226, for example, a hole injection layer/hole transfer layer and an electron transfer layer/electron injection layer are provided to sandwich the light-emitting layer 226. In this embodiment, the light-emitting layer 226 is formed of an organic material which emits white light, and full color display is realized by color filters 234.

It is preferable that the pixel electrode 222 is formed of a metal material having a high reflectance in order to allow light generated in the light emitting-layer 226 to be reflected toward the common pixel electrode 224. Alternatively, the pixel electrode 222 may have a stack structure of a metal film and a transparent conductive film, so that the pixel electrode 222 includes a light-reflective surface.

It is preferable that the common pixel electrode 224 is formed of a light-transmissive conductive material such as ITO (tin oxide-containing indium oxide) or IZO (indium oxide-zinc oxide) in order to allow light generated in the light-emitting layer 226 pass through the common electrode 224. Alternatively, the common electrode 224 may be formed of a metal layer having such a thickness that allows the light generated in the light-emitting layer 226 to pass through the metal layer.

It is preferable that a sealing layer 232 is provided on the common electrode 224. In, for example, an organic EL display device using an organic EL element as the light-emitting element 220, the following phenomenon may occur. An organic EL layer is highly vulnerable to moisture. Therefore, if moisture enters the inside of the panel from outside and reaches the organic EL layer, light emission defect points called “dark spots” may be generated. For this reason, it is preferable that the sealing layer 232 is formed of an insulating material that blocks the entrance of moisture. The sealing layer 232 may be formed of a multi-film layer containing an inorganic insulating material and an organic insulating material. Inorganic insulating materials usable for the sealing layer 232 include SiOx, SixNy, SiOxNy, SiNxOy, AlxOy, AlxNy, AlxOyNz, AlxNyOz, and the like (x, y and z are each an arbitrary value). Organic insulating materials covering the inorganic insulating film formed of any of the above-listed materials include a polyimide resin, an acrylic resin, an epoxy resin, a silicone resin (siloxane resin), a fluorine resin, and the like.

### [Method for Manufacturing the Display Device]

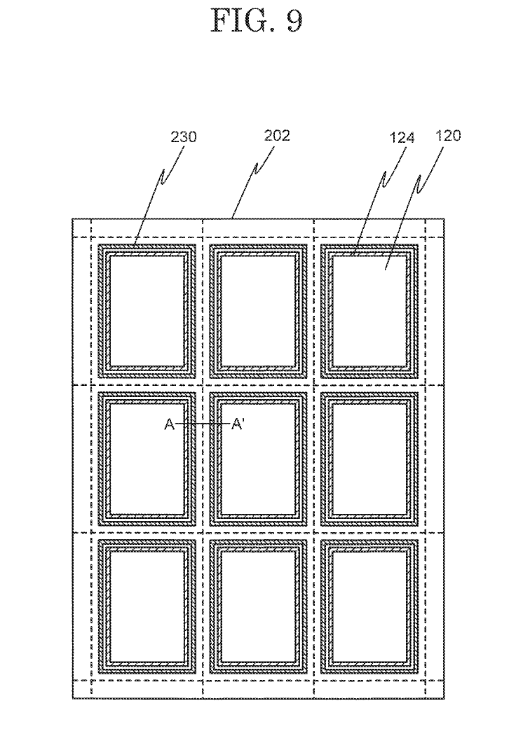

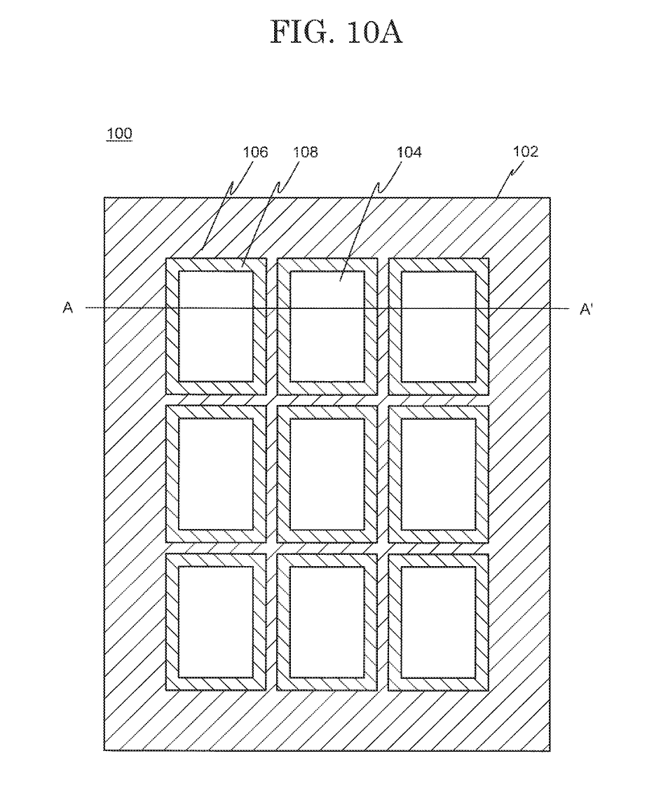

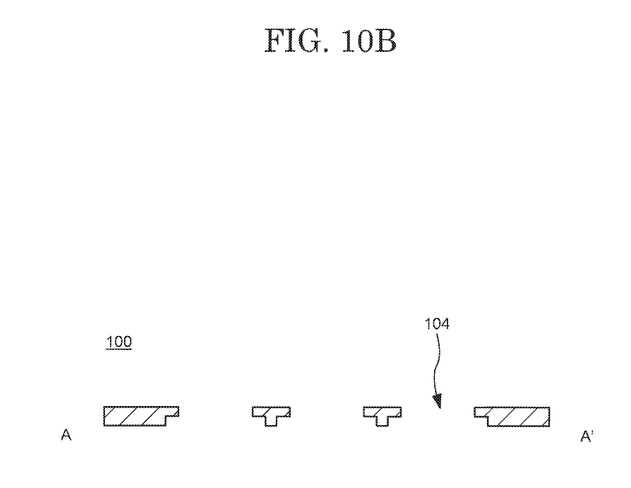

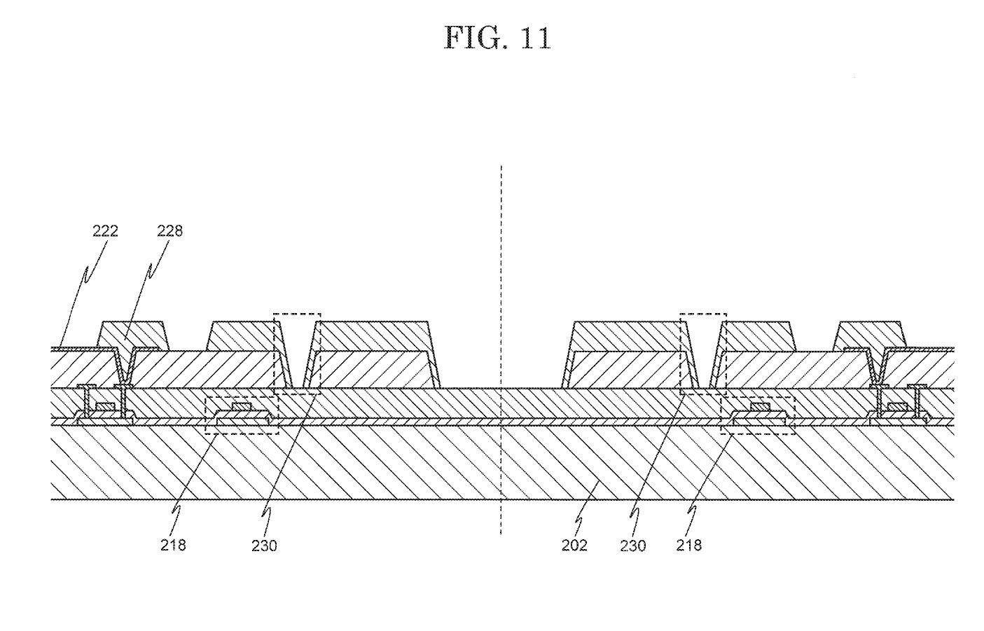

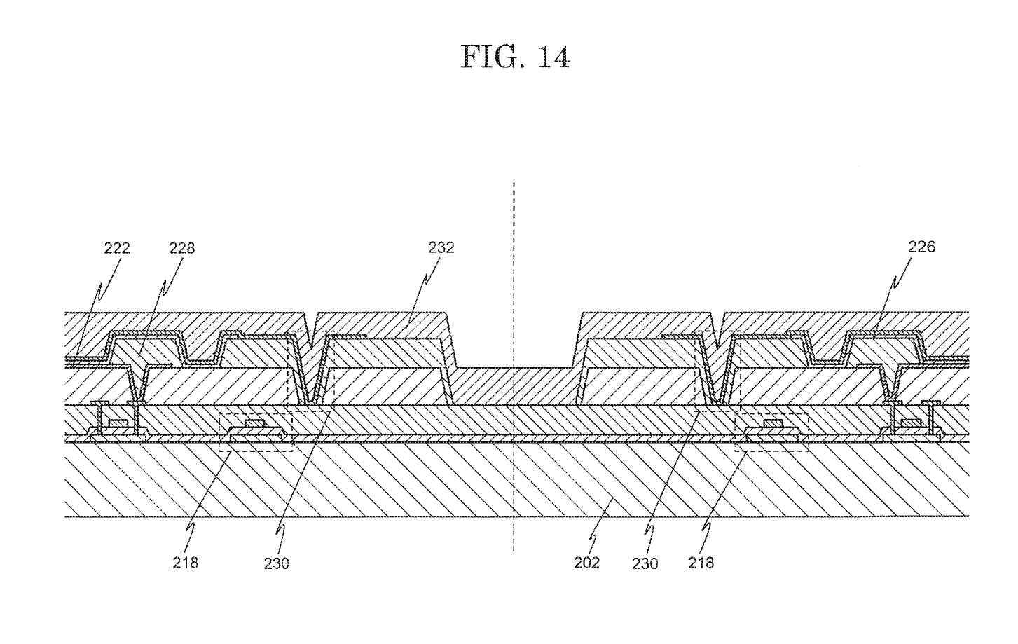

A method for manufacturing the display device 200 using the film forming method according to the present invention will be described with reference to the figures. FIG. 9 is a plan view showing the method for manufacturing the display device 200 in this embodiment. FIG. 10A and FIG. 10B are respectively a plan view and a cross-sectional view of the film-forming mask 100 usable for the method for manufacturing the display device 200 in this embodiment. FIG. 11 through FIG. 14 are cross-sectional views showing the method for manufacturing the display device 200 in this embodiment. FIG. 11 through FIG. 14 are each a cross-sectional view showing a state before an assembly of the display devices 200 are divided into individual display devices 200, and are taken along line A-A′ in FIG. 9.

FIG. 11 is a cross-sectional view showing a state where the pixel electrode 222 is formed on the first substrate 202 as well as other layers formed before the pixel electrode 222. The steps before this state will not be described in detail.

After the pixel electrode 222 is formed, the light-emitting layer 226 is formed. The light-emitting layer 226 is formed over the plurality of pixels 208 located in the display region 206. The plan view of FIG. 9 shows the film forming region 120, the contact prohibited region 124, and the sealing region 230 of the light-emitting layer 226. In this example, the contact prohibited region 124 encloses the film forming region 120.

The film forming region 120 corresponds to the display region 206. The contact prohibited region 124 is also referred to as a “driving circuit region” because a driving circuit including the transistor is located in the contact prohibited region 124. The sealing region 230 encloses the display region 206 (film forming region 120) and the driving circuit region (contact prohibited region 124), and divides the organic layers located in the display region 206 and the driving circuit region (contact prohibited region 124) into island-like areas. Namely, in this embodiment, the driving circuit region (contact prohibited region 124) encloses the display region 206.

More specifically, the following layers are formed on the film forming surface of the first substrate 202. The display region 206 (film forming region 120) including the plurality of pixel electrodes 222 forming the plurality of pixels is formed. The driving circuit region (contact prohibited region 124) including a transistor 218 is formed outer to the display region 206. The sealing region 230 enclosing the display region 206 (film forming region 120) is formed outer to the driving circuit region (contact prohibited region 124).

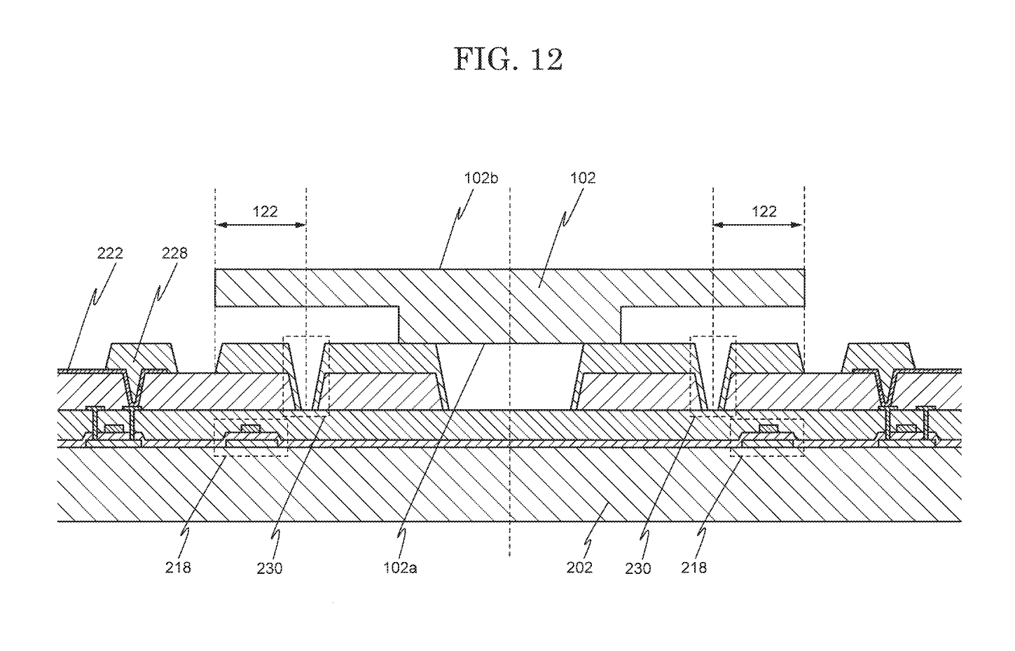

In this embodiment, vapor deposition is performed by use of the film-forming mask 100 to form the light-emitting layer 226 by deposition and patterning. FIG. 12 is a cross-sectional view showing the state where the film-forming mask 100 usable to form the light-emitting layer 226 shown in FIG. 10A and FIG. 10B is in contact with the film forming surface of the first substrate 202.

The film-forming mask 100 includes the first surface 102a facing the film forming surface of the first substrate 102 and the second surface 102b opposite to the first substrate 102a. The film-forming mask 100 also includes an opening exposing the display device 206 (film forming region 120). The film-forming mask 100 is thinned from the side of the first surface 102a in at least an area including the driving circuit region (contact prohibited region 124). The first surface 102a of the film-forming mask 100 is put into contact with the film forming surface.

The film formation prohibited region 122 needs to include the sealing region 230. Namely, the light-emitting layer 226 should not be deposited in the sealing region 230. If the light-emitting layer 226 is deposited in the sealing region 230, the light-emitting layer 226 acts as a transporting pass for moisture, and the moisture entering the display device 200 from outside passes the sealing region 230 and enters the pixels in the display region 206. In this state, the sealing region 230 does not play the role thereof.

In this example, the contact prohibited region 124, in which a circuit including the transistor 218 and the like is located, is present in the film formation prohibited region 122. With the film forming method in this embodiment, the transistor 218 overlaps the second shielding area 208 of the film-forming mask 100. Therefore, the transistor 218 or the like is prevented from directly contacting the film-forming mask 100 or from being destroyed by a dent of the film-forming mask 100 during film formation.

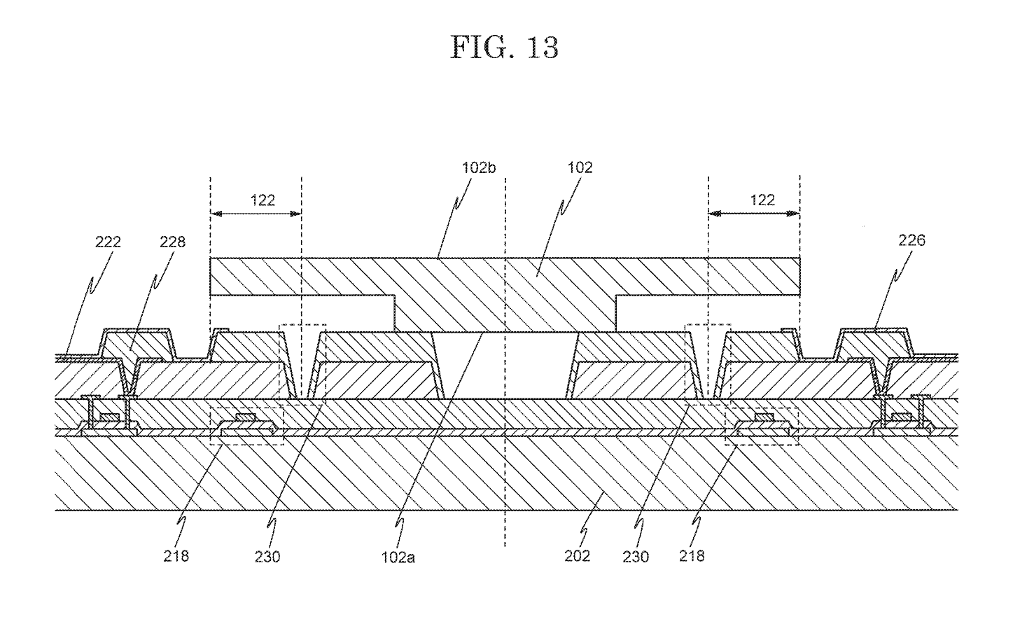

The light-emitting layer 226 containing an organic material is formed through the film-forming mask described above. FIG. 13 is a cross-sectional view showing the state where the light-emitting layer 226 is formed after the state shown in FIG. 12.

As described above, the film forming method in this embodiment allows the light-emitting layer 226 to be selectively deposited on areas corresponding to the openings 104 of the film-forming mask 100, and also avoids a damage from being caused by the contact of the film-forming mask 100 and the film forming surface of the first substrate 202. This improves the yield of the display devices 200, and the manufactured display device 200 is highly reliable.

After the light-emitting layer 226 is formed, the common electrode 224 and the sealing layer 232 are formed. Thus, manufacturing steps on the first substrate 202 side (array substrate side) are completed.

The common electrode 224 may be formed so as to cover the light-emitting layer 226 and the sealing region 230. This efficiently separates the organic films along the sealing region 230. The manufactured display device 200 has an improved resistance against entrance of moisture.

The sealing layer 232 covers the common electrode 224, and may contain an inorganic insulating material. It is preferable that the sealing layer 232 is formed of an insulating material that blocks the entrance of moisture. The sealing layer 232 may be formed of a multi-film layer containing an inorganic insulating material and an organic insulating material. Inorganic insulating materials usable for the sealing layer 232 include SiOx, SixNy, SiOxNy, SiNxOy, AlxOy, AlxNy, AlxOyNz, AlxNyOz, and the like (x, y and z are each an arbitrary value). Organic insulating materials covering the inorganic insulating film formed of any of the above-listed materials include a polyimide resin, an acrylic resin, an epoxy resin, a silicone resin (siloxane resin), a fluorine resin, and the like. Thus, the manufactured display device 200 has an improved resistance against entrance of moisture.

The film-forming mask and the film forming method using the same in preferable embodiments according to the present invention are described above. These embodiments are merely examples, and the technological scope of the present invention is not limited to any of these embodiments. For example, the film forming method according to the present invention is described regarding the formation of a light-emitting layer. The film forming method according to the present invention is not limited to being used for a light-emitting layer, and is also applicable to formation of any film using a film-forming mask.

A person of ordinary skill in the art would make various alterations without departing from the gist of the present invention. Therefore, such alterations are to be construed to be encompassed in the technological scope of the present invention.

What is claimed is:

1. A film-forming mask, comprising:
a mask body having a first surface facing a film forming surface, a second surface opposite to the first surface, and an opening exposing a part of the film forming surface;
wherein the mask body is thinned from the side of the first surface along an edge of the opening.

2. The film-forming mask according to claim 1, wherein an area of the mask body thinned encloses the opening.

3. The film-forming mask according to claim 1, wherein:
the mask body has an array of a plurality of the openings; and
the area of the mask body thinned encloses all the plurality of openings.

4. The film-forming mask according to claim 1, further comprising a mask frame provided along an outer periphery of the mask body.

5. A film forming method performed by use of the film-forming mask according to claim 1.

6. A method for manufacturing a display device, comprising:
forming, on a film forming surface of a substrate, a display region including a plurality of pixel electrodes forming a plurality of pixels, a driving circuit region including a transistor, the driving circuit region being formed outer to the display region, and a sealing region enclosing the display region, the sealing region being formed outer to the driving circuit region;
putting a first surface of a film-forming mask into contact with the film forming surface, the film-forming mask including the first surface facing the film forming surface, a second surface opposite to the first surface, and an opening exposing the display region, the mask being thinned from the side of the first surface in at least a region including the driving circuit region; and
forming a light-emitting layer containing an organic material.

7. The method for manufacturing a display device according to claim 6, wherein the driving circuit region encloses the display region.

8. The method for manufacturing a display device according to claim 6, further comprising forming a common electrode covering the light-emitting layer and the sealing region.

9. The method for manufacturing a display device according to claim 8, further comprising forming a sealing layer covering the common electrode.
